(19) United States
(12) Patent Application Publication
(10) Pub. No.: US 2026/0268963 A1
(43) Pub. Date: Sep. 10, 2026

(54) HIGH BANDWIDTH DIMM ARCHITECTURE

(71) Applicant: TACHYUM LTD., Las Vegas, NV (US)

(72) Inventors: Radoslav DANILAK, Henderson, NV (US); Pinchas HERMAN, Sunnyvale, CA (US); William RADKE, Santa Cruz, CA (US); Rodney MULLENDORE, San Jose, CA (US)

(73) Assignee: TACHYUM LTD., Las Vegas, NV (US)

(21) Appl. No.: 19/071,297

(22) Filed: Mar. 5, 2025

(51) Int. Cl. G11C 11/4093

(52) U.S. Cl. CPC G11C 11/4093

(57) ABSTRACT

A DIMM is provided. The DIMM includes Double Data Rate (DDR) chips, a plurality of first data buffers, each of the first data buffers being connected to at least two of the DDR chips. Each first data buffers include: a Pulse Amplitude Modulation 3-level (PAM3)-binary decoder configured to convert incoming data PAM3 signals from a pin array into one or more incoming 8-bit data signals; a data demultiplexer configured to forward the one or more incoming 8-bit data signals toward an appropriate one of the connected at least two DDR chips; a multiplexer configured to receive outgoing 8-bit data signals from the connected at least two DDR chips; and a binary-PAM3 binary encoder configured to convert the outgoing 8-bit data signals from the multiplexer into outgoing PAM3 signals and to forward the outgoing PAM3 signals toward the pin array.

### FIELD OF THE INVENTION

Various embodiments described herein generally relate to DIMM architecture. More specifically, various embodiments relate to a DIMM architecture that utilizes DDR x16 chips.

### BACKGROUND

Dynamic random-access memory (DRAM) is a type of semiconductor memory that is typically used for the data or program code needed by a computer processor to function. DRAM is a common type of random-access memory (RAM) that is used in personal computers (PCs), laptops, workstations, and servers. DRAMs are typically provided as integrated circuit chips. DRAM chips currently support data widths of 4 (x4), or 8 (x8), or 16 (x16) bits. Synchronous dynamic random-access memory (SDRAM) is a DRAM where an externally supplied clock signal coordinates the operation of its external pin interface.

A dual in-line memory module (DIMM) is a memory stick with a collection of several SDRAMs populating a printed circuit board. The stick is plugged into a socket of a computing device (e.g., server, personal computer, laptop, tablet, special purpose device, etc.)

Some DIMM layouts have been set as standards to permit industry sources to universally manufacture compliant components. Double Data Rate 5 (DDR5) DIMMs have significant advantages over DDM4 DIMMs. DDR6 DIMMs are on the horizon.

There has recently been an interest in utilizing DIMM with x16 DDR5 chips. However, there is no specific architecture available to support the same within the size standards of DIMMs. Specifically, standard DIMM architecture for DDR5 x8 will not support DDR5 x16 chips because DDR5 x16 chips would require twice as many pins and twice as many data buffers. The standard size for DIMM chips simply cannot accommodate the corresponding physical space.

### SUMMARY

According to an embodiment, a Dual In-line Memory Module (DIMM), is provided. The DIMM may include: a plurality Double Data Rate (DDR) chips; a pin array; a plurality of first data buffers, each of the first data buffers being connected to at least two of the DDR chips; and a registered clock driver (RCD). Each of the first data buffers includes: a Pulse Amplitude Modulation 3-level (PAM3)-binary decoder configured to convert incoming data PAM3 signals from the pin array into one or more incoming 8-bit data signals; a data demultiplexer configured to forward the one or more incoming 8-bit data signals toward an appropriate one of the connected at least two DDR chips; a multiplexer configured to receive outgoing 8-bit data signals from the connected at least two DDR chips; and a binary-PAM3 binary encoder configured to convert the outgoing 8-bit data signals from the multiplexer into outgoing PAM3 signals and to forward the outgoing PAM3 signals toward the pin array. The RCD may include: a PAM3-binary converter configured to convert incoming driver PAM3 signals into binary driver signals; and at least one driver demultiplexer and at least one RCD buffer configured to forward at least a portion of the binary driver signals to appropriate ones of the plurality of DDR chips.

The above embodiment may have various optional features. The plurality of DDR chips may be DDR5 chips. The plurality of DDR chips may be grouped into first, second, third and fourth sets of DDR chips. Each of the sets of DDR chips may include 9 DDR x16 chips. The at least one driver demultiplexer may include first and second driver demultiplexers and the and at least one RCD buffer comprises first, second, third and fourth RCD buffers, the first driver demultiplexer being connected to the first and the second RCD buffers, the first RCD buffer being connected to the first set of DDR chips by at least one first bus, and the second RCD buffer connected to the second set of DDR chips by at least one second bus, the second driver demultiplexer being connected to the third and the fourth RCD buffers, and the third RCD buffer being connected to the third set of DDR chips by at least one third bus, and the fourth RCD buffer connected to the fourth set of DDR chips by at least one fourth bus. Each of the first data buffers may have on a first side thirteen pins for receiving eleven PAM3 signals and two clock signals. The two clock signals may be Non-Return to Zero (NRZ) signals. Each of the first data buffers may have on a second side four eight-bit data channels and four clock pair channels to communicate with the at least two connected DDR chips. Each of the DDR chips may be connected to one of the first data buffers by two of the four eight-bit data channels and two of the four clock pair channels. The data demultiplexer configured to forward the one or more incoming 8-bit data signals toward an appropriate one of the connected two DDR chips may include the data demultiplexer being configured to select for a particular 8-bit data signal one of the four eight-bit data channels to forward the particular 8-bit data signal to. The DIMM may further include a system controller in communication with the DIMM, the system controller being configured to communicate PAM3 format data and control signals with the DIMM.

According to another embodiment, a Dual In-line Memory Module (DIMM), is provided. The DIMM may include a plurality Double Data Rate (DDR) chips, the DDR chips being DDR5 x16 chips; a pin array; a plurality of first data buffers, each of the first data buffers being connected to two of the DDR chips; and a registered clock driver (RCD). Each of the first data buffers may include: a Pulse Amplitude Modulation 3-level (PAM3)-binary decoder configured to convert incoming data PAM3 signals from the pin array into one or more incoming 8-bit data signals; a data demultiplexer configured to forward the one or more incoming 8-bit data signals toward an appropriate one of the connected two DDR chips; a multiplexer configured to receive outgoing 8-bit data signals from the connected two DDR chips; and a binary-PAM3 binary encoder configured to convert the outgoing 8-bit data signals from the multiplexer into outgoing PAM3 signals and to forward the outgoing PAM3 signals toward the pin array. The RCS may include: a PAM3-binary converter configured to convert incoming driver PAM3 signals into binary driver signals; and at least one driver demultiplexer and at least one RCD buffer configured to forward at least a portion of the binary driver signals to appropriate ones of the plurality of DDR chips.

The above embodiment may have various optional features. Each of the first data buffers may have on a first side thirteen pins for receiving eleven PAM3 signals and two clock signals. The two clock signals may be Non-Return to Zero (NRZ) signals. Each of the first data buffers may have on a second side four eight-bit data channels and four clock pair channels to communicate with the two connected DDR chips. The data demultiplexer configured to forward the one or more incoming 8-bit data signals toward an appropriate one of the connected two DDR chips may include the data demultiplexer being configured to select for a particular 8-bit data signal one of the four eight-bit data channels to forward the particular 8-bit data signal to.

According to another embodiment, a dual in-line memory module (DIMM) is provided. The DIMM includes: a plurality Double Data Rate (DDR) chips; a pin array; a plurality of first data buffers, each of the first data buffers being connected to four of the DDR chips; and a registered clock driver (RCD). Each of the first data buffers may include: a Pulse Amplitude Modulation 3-level (PAM3)-binary decoder configured to convert incoming data PAM3 signals from the pin array into one or more incoming 8-bit data signals; a data demultiplexer configured to forward the one or more incoming 8-bit data signals toward an appropriate one of the connected four DDR chips; a multiplexer configured to receive outgoing 8-bit data signals from the connected four DDR chips; a binary-PAM3 binary encoder configured to convert the outgoing 8-bit data signals from the multiplexer into outgoing PAM3 signals and to forward the outgoing PAM3 signals toward the pin array. The registered clock driver (RCD) may include: a PAM3-binary converter configured to convert incoming driver PAM3 signals into binary driver signals; and at least one driver demultiplexer and at least one RCD buffer configured to forward at least a portion of the binary driver signals to appropriate ones of the DDR chips.

The above embodiment may have various optional features. The DDR chips may be DDR5 chips. The plurality of DDR chips may be grouped into first, second, third and fourth sets of DDR chips. Each set of DDR chips may include 18 DDR x8 chips.

### DRAWINGS

Various embodiments in accordance with the present disclosure will be described with reference to the drawings, as follows.

FIG. 1 shows a DDR5 x8 chip DIMM architecture.

FIG. 2 shows a data buffer of the architecture of FIG. 1.

FIG. 3 shows an RCD of the architecture of FIG. 1.

FIG. 4 shows a DDR5 x16 chip DIMM architecture according to an embodiment.

FIG. 5 shows a data buffer of the architecture of FIG. 4.

FIG. 6 shows an RCD of the architecture of FIG. 4.

FIG. 7 shows a DDR5 x8 chip DIMM architecture according to another embodiment.

FIGS. 8A and 8B show a DDR5 x8 chip DIMM architecture according to an embodiment.

FIG. 9 shows a data buffer of the architecture of FIGS. 8A and 8B.

FIG. 10 shows a supporting environment for the architecture of FIG. 4 or 7.

### DETAILED DESCRIPTION

In the following description, various embodiments will be illustrated by way of example and not by way of limitation in the figures of the accompanying drawings. References to various embodiments in this disclosure are not necessarily to the same embodiment, and such references mean at least one. While specific implementations and other details are discussed, it is to be understood that this is done for illustrative purposes only. A person skilled in the relevant art will recognize that other components and configurations may be used without departing from the scope and spirit of the claimed subject matter.

Specific details are provided in the following description to provide a thorough understanding of embodiments. However, it will be understood by one of ordinary skill in the art that embodiments may be practiced without these specific details. For example, systems may be shown in block diagrams so as not to obscure the embodiments in unnecessary detail. In other instances, well-known processes, structures and techniques may be shown without unnecessary detail in order to avoid obscuring example embodiments.

References to one or an embodiment in the present disclosure can be, but not necessarily are, references to the same embodiment; and, such references mean at least one of the embodiments.

References to any “example” herein (e.g., “for example”, “an example of”, by way of example” or the like) are to be considered non-limiting examples regardless of whether expressly stated or not.

Reference to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various features are described which may be features for some embodiments but not other embodiments.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any exemplified term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Several definitions that apply throughout this disclosure will now be presented.

The terms “substantial”, “substantially” or the like are defined to be essentially conforming to the particular dimension, shape, or other feature that the term modifies, such that the component need not be exact. For example, “substantially cylindrical” means that the object resembles a cylinder, but can have one or more deviations from a true cylinder. The terms are used as a modifier to imply “approximate” rather than “perfect.” It is a term of approximation, not a term of degree.

The term “comprising” when utilized means “including, but not necessarily limited to”; it specifically indicates open-ended inclusion or membership in the so-described combination, group, series and the like.

The term “a” means “one or more” unless the context clearly indicates a single element.

The term “about” when used in connection with a numerical value means a variation consistent with the range of error in equipment used to measure the values, for which ±5% may be expected. “First,” “second,” etc., re labels to distinguish components or blocks of otherwise similar names but does not imply any sequence or numerical limitation. “And/or” for two possibilities means either or both of the stated possibilities (“A and/or B” covers A alone, B alone, or both A and B take together), and when present with three or more stated possibilities means any individual possibility alone, all possibilities taken together, or some combination of possibilities that is less than all of the possibilities. The language in the format “at least one of A. and N” where A through N are possibilities means “and/or” for the stated possibilities (e.g., at least one A, at least one N, at least one A and at least one N, etc.).

When an element is referred to as being “connected,” or “coupled,” to another element, it can be directly connected or coupled to the other element or intervening elements may be present. By contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

As used herein, the term “front”, “rear”, “left,” “right,” “top” and “bottom” or other terms of direction, orientation, and/or relative position are used for explanation and convenience to refer to certain features of this disclosure. However, these terms are not absolute and should not be construed as limiting this disclosure.

Shapes as described herein are not considered absolute. As is known in the art, surfaces often have waves, protrusions, holes, recesses, etc. to provide rigidity, strength and functionality. All recitations of shape (e.g., cylindrical) herein are to be considered modified by “substantially” regardless of whether expressly stated in the disclosure or claims, and specifically accounts for variations in the art as noted above.

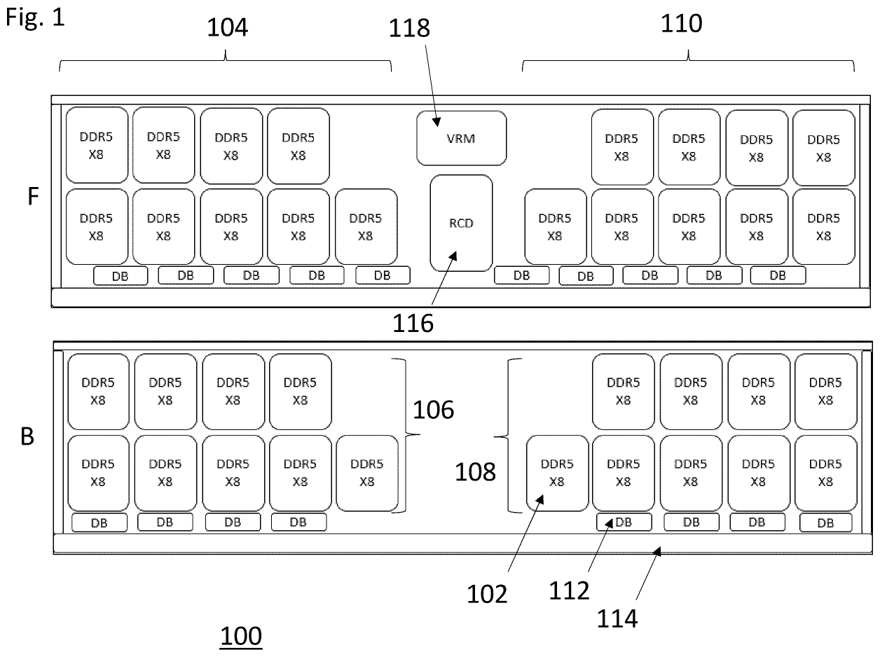

Referring now to FIG. 1, a front (F) and back (B) side of a DIMM 100 with DDR5 chips 102 is shown. The DDR5 chips 102 are x8 chips and allocated into four groups 104, 106, 108, and 110.

Data buffers 112 are provided between the DDR5 chips 102 and the connector pin array 114. Each data buffer 112 connects to and communicates with a pair of the DDR5 chips 102, the pair being with one DDR5 chip 102 on the front side and another DDR5 chip 102 on the back side.

The front side of DIMM 100 supports a Register Clock Driver (RCD) 116 which provides the known role as buffer or intermediary between the memory controller and the memory chips. The front side of DIMM 100 supports a voltage Regulator Module 118 to regulate the voltage to the DDR5 chips 102.

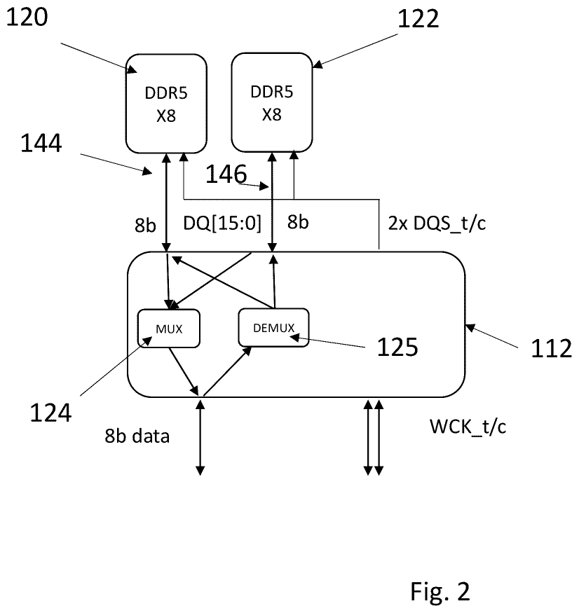

Referring now to FIG. 2, data buffer 112 is shown in more detail. On the pin facing side, data buffer 112 receives an 8-bit data signal, along with two clock signals WCK_t/c. Both the 8-bit data signal and two clock signals are in a binary format such as Non-Return to Zero (NRZ) format, which refers to a type of encoding scheme used for transmitting binary data. The signals require ten pins on the connector pin array 114 facing side of the data buffer 112 to receive the 8-bit signal and the two clock signals.

On a DDRchip 102 facing side, data buffer 112 has two 8-bit data buses 144 and 146. Each of 8-bit data buses 144 and 146 connect with a specific one of DDR5 chips 102, shown as 120 and 122. For minimized layout purposes, DDRchips 120 and 122 may be aligned on opposite sides of the DIMM 100.

The data buffer 112 includes a 1-2 demultiplexer 125 for received NRZ 8-bit data signals. Demultiplexer 125 assigns received 8-bit data signals to one of the two 8-bit data buses 144 and 146, which sends the signals to the corresponding DDRchip 120 or 122.

The data buffer 112 also includes a 2-1 multiplexer 124 that receives NRZ 8-bit data signals from DDRchip 120 or 122 via the two 8-bit data buses 144 and 146 and multiplexes them out as 8-bit signals toward the connector pin array114 for travel to their next destination.

The data buffer 112 also receives the two clock signals WCK_t/c and outputs them as appropriate strobe signals in the form of two DQS_t/c pairs to support the two DDRchips 120 and 122.

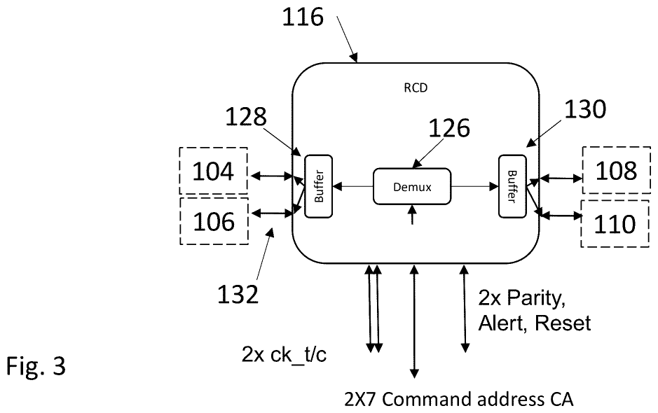

Referring now to FIG. 3, the RCD 116 is shown in more detail. On a connector pin array 114 facing side, RCD 116 has pins to receive as input two clock signals (ck_t/c pair), 2×7 Command Address CA signals and a reset signal, and as output 2× parity signals, and an alert signal. All these signals are in NRZ format. The signals require a total of 22 pins (2×7 for the command address, 2×2 for the clock signals, 2× parity, alert, plus reset).

RCD 116 includes a demultiplexer 126 that demultiplexes signals for the DDRchip groups 104-110 through RCD buffers 128 and 130 and buses 132, for which at least one bus is provided between each RCD buffer and the corresponding DDRchip set.

The DIMM 100 shown in FIG. 3 cannot be converted directly into DDR5 x16 chips by swapping out DDR5 x8 chips with DDR5 x16 chips. It would require double the number of data buffers 112 (nine more in FIG. 1), an extra RCD, and an additional 112 pins (ten each for the additional data buffers 112, and 22 for the additional RCD. DIMM 100 simply does not have the area to accommodate these additional components within the size standards.

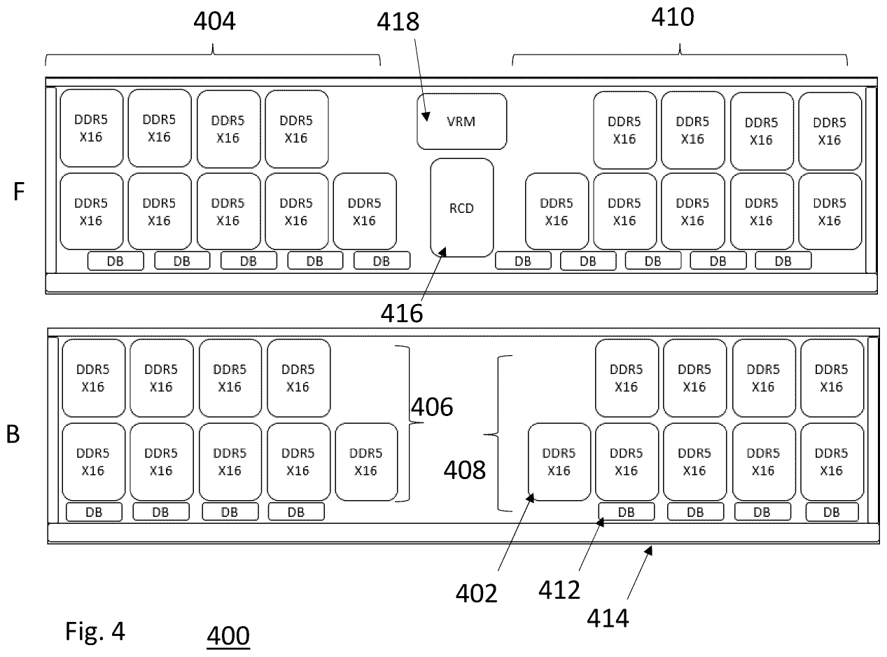

Referring now to FIG. 4, a DIMM 400 for DDR5 x16 chips is shown in front (F) and back (B) side. The DDR5 chips 402 are allocated into four groups 404, 406, 408, and 410.

Data buffers 412 are provided between the DDR5 x16 chips 402 and the connector pin array 414. Each data buffer 412 connects to and communicates with a pair of the DDR5 x16 chips 402, the pair being with one DDR5 x16 chip 402 on the front side and another DDR5 x16 chip 402 on the back side.

The front side of DIMM 400 supports a Register Clock Driver (RCD) 416 which provides the known role as buffer or intermediary between the memory controller and the memory chips. The front side of DIMM 100 also supports a Voltage Regulator Module 418 to regulate the voltage to the DDR5 x16 chips 402. Other components per the DDR5 standard as are known in the art (e.g., PMIC, SPD hub, temperature sensor, wiring, connectors, etc.) are not shown.

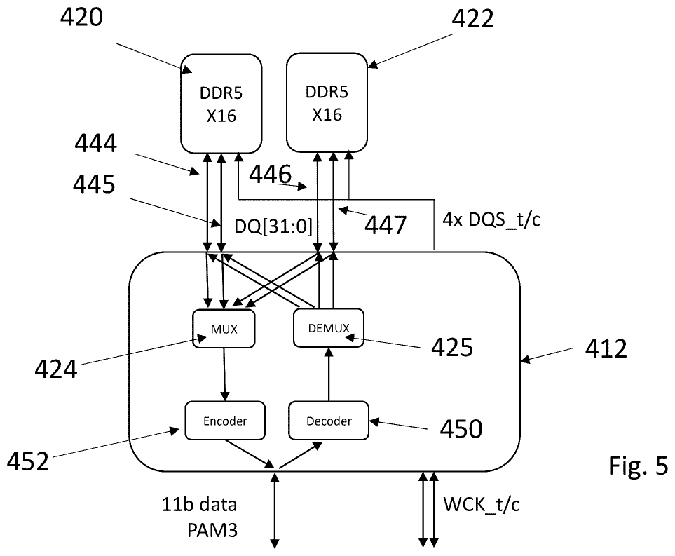

Referring now to FIG. 5, data buffer 412 is shown in more detail. On the pin facing side, data buffer 412 receives an 11-bit data signal, along with two clock signals WCK_t/c. The 11-bit data signal is in Pulse Amplitude Modulation 3-level (PAM3) format, while the clock signals are in NRZ format. The signals use thirteen pins on the connector pin array 114 facing side of the data buffer 412 to receive the 11-bit PAM3 signal and the two clock signals.

On a DDRchip 402 facing side, data buffer 412 has four 8-bit data buses 444, 445, 446, and 447. Each DDR5 x16 chip 402 is made up of two DDR5 x8 chips in a single package, or a single die in the same package. Pairs of 8-bit data buses 414/415 and 416/417 each connect with its own DDR5 x16 chips 402, shown as 420 and 422. For minimized layout purposes, chips 420 and 422 may be aligned on opposite sides of the DIMM 400.

The data buffer 412 includes a PAM3-binary decoder 450 that converts the received PAM3 signals into 8-bit NRZ format. A 1-4 demultiplexer 425 then assigns the decoded 8-bit signal to one of the four data buses 414/415/416/417, which sends the signals to the corresponding DDRchip 420 or 422.

The data buffer 412 also includes a 4-1 multiplexer 424 that receives 8-bit data signals from DDRchip 420 or 422 via the four 8-bit data buses 414/415/416/417, and multiplexers them out as 8-bit signals in NRZ format. A binary-PAM3 encoder 452 then encodes the 8-bit signals into an 11-bit signal PAM3 format and forwards the 11-bit signal PAM3 format to the connector pin array 414 for travel to their next destination.

The data buffer 412 also receives the two clock pair signals WCK_t/c and outputs them as appropriate strobe signals DQS[3:0]_t/c pairs to support the two DDR5 x16 chips 420 and 422.

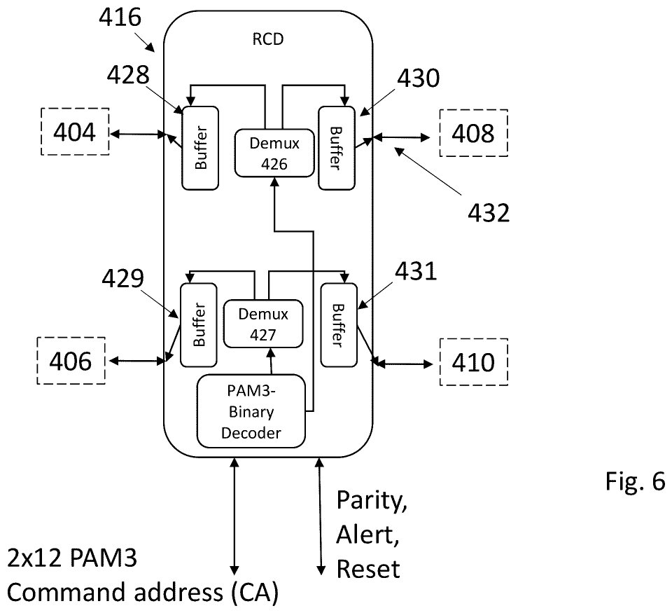

Referring now to FIG. 6, the RCD 416 is shown in more detail. On the bottom/connector pin array 414 facing side, RCD 416 has input pins to receive 2×12 PAM3 Command Address CA signals, and as output pins a parity signal, an alert signal, and a reset signal. The PAM3 Command Address CA signals are in PAM3 format, and the other signals are in NRZ format. The signals require a total of 27 pins (2×12 for the command address, and one each for the parity, alert, plus reset).

RCD 416 includes PAM3-binary decoder 450 that converts the received PAM3 signals into two command and address CA_[7:0] control signals and two chip select CS_[1:0] in NRZ format for two sets of 11 control bits. The control signals are fed to two demultiplexers 426 and 472 that demultiplexes the control signals to assign them to the appropriate DDRchip sets 404-410 through RCD buffers 428, 429, 430, and 431 over at least one bus 432. At least one bus 432 is provided between each RCD buffer and its corresponding DDRchip group.

Each of the 11-bit PAM3 data signals includes 1.5 bits of data per the PAM3 standard, such that 11 signals carry 33 bits of data per clock cycle. Of these, 32 can be allocated to the data processing for double the speed (via the DDR5 x16 chips 402) at double the bandwidth compared to the data buffer 112 of DIMM 100, while the remaining bit can be reserved for other purposes.

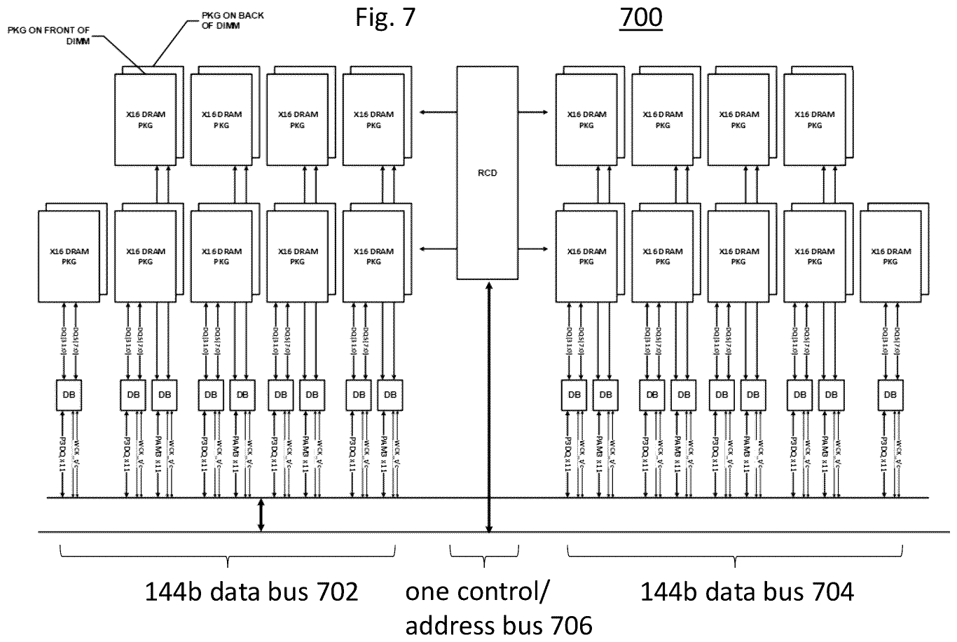

Referring now to FIG. 7, another version of the architecture of a DIMM 700 is shown. DIMM 700 corresponds to DIMM 400, for which FIG. 7 shows more detail in the connections between the data buffers and the DDRchips. The architecture allows for two 144b data buses 702 and 704, one for each side of the DIMM 700 (one bus 702 for DDRchips on the left/front and right/rear, and the other bus 704 for DDRchips on the right/front and left/rear), plus one bus for control and address signals for the RCD.

The double speed and double bandwidth improvement of DIMM 400/700 is achieved with the same number of data buffers 412 and RCDs 416 as DIMM 100, and with only another 27 pins needed for the data buffers 412 and five pins needed for the RCD 416. The additional 32pins can be accommodated within the existing size and shape of DDR5 DIMMs per the standard, using pins of slightly smaller width relative to the width of the DIMM 400/700 itself.

The disclosure above shows nine DDR5 x16 chips 402 in each set 404-410. However, the invention is not so limited, and any set may include any number of chips up to a maximum of the size that the DIMM itself can accommodate. The chips could also be to standards other than DDR5, such as DDR4 or DDR6.

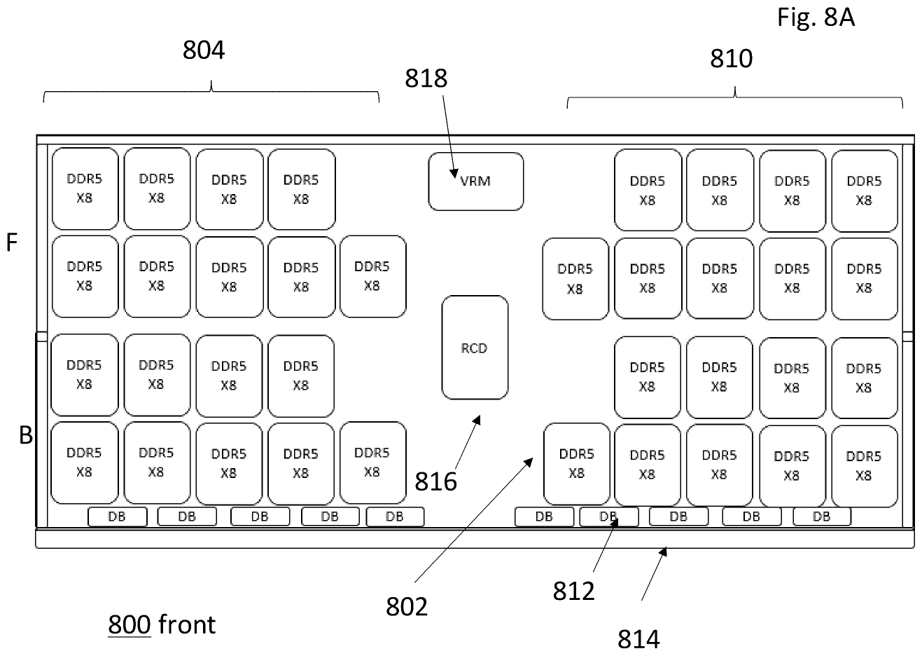

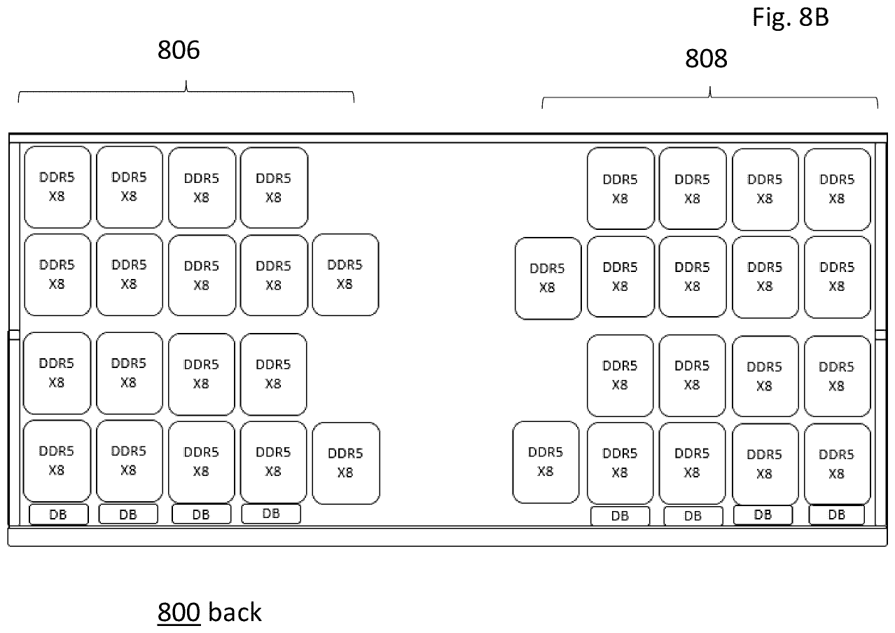

Referring now to FIG. 8A and B, front and back sides of a DIMM 800 are shown. DIMM 800 has a physical size consistent with what is being referred to as a “tall” DIMM, in which four rows of DDRchips 802 are present. The DDRchips 802 are DDR5 x8, chips, but the invention is not so limited, and other chips may be used. The DDR5 chips 802 are allocated into four groups 804, 806, 808, and 810.

Data buffers 812 are provided between the DDR5 x8 chips 802 and the connector pin array 814. Each data buffer 812 connects to and communicates with four of the DDR5 x8 chips 802, with two DDR5 x8 chips 802 on the front side and another two DDR5 x8 chips 802 on the back side.

The front side of DIMM 800 supports a Register Clock Driver (RCD) 816 which provides the known role as buffer or intermediary between the memory controller and the memory chips. The front side of DIMM 100 also supports a Voltage Regulator Module 818 to regulate the voltage to the DDR5 x8 chips 802. Other components per the DDR5 standard as are known in the art (e.g., PMIC, SPD hub, temperature sensor, wiring, connectors, etc.) are not shown.

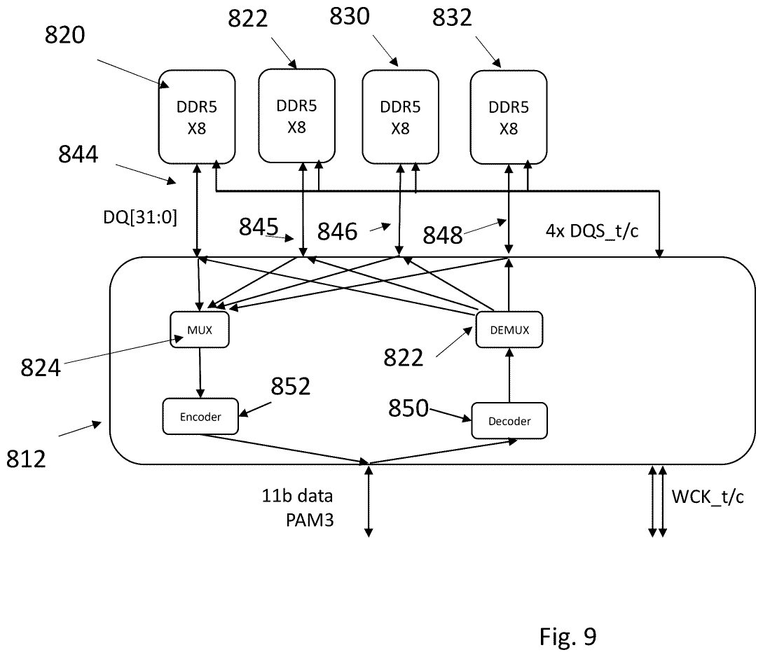

Referring now to FIG. 9, data buffer 812 is shown in more detail. On the pin facing side, data buffer 812 receives an 11-bit data signal, along with two clock signals WCK_t/c. The 11-bit data signal is in Pulse Amplitude Modulation 3-level (PAM3) format, while the clock signals are in NRZ format. The signals require thirteen pins on the bottom/connector pin array 814 facing side of the data buffer 812 to receive the 11-bit PAM3 signal and the two clock signals.

On a DDRchip 802 facing side, data buffer 812 has four 8-bit data buses 844, 845, 846, and 847. Each 8-bit data bus 814/815/816/817 connects with its own DDR5 x8 chip 802, shown as 820/822/830/832.

The data buffer 812 includes a PAM3-binary decoder 850 that converts the received PAM3 signals into 8-bit NRZ format. A 1-4 demultiplexer 822 then assigns the decoded 8-bit signal to one of the four data buses 814/815/816/817, which sends the signals to the corresponding DDRchip 820/822/830/832.

The data buffer 812 also includes a 4-1 multiplexer 824 that receives 8-bit data signals from DDRchips 820/822/830/832 via the four 8-bit data buses 814/815/816/817, and multiplexers them out as 8-bit signals in NRZ format. A binary-PAM3 encoder 852 then encodes the 8-bit signals into an 11-bit signal PAM3 format and forwards the 11-bit signal PAM3 format to the connector pin array 814 for travel to their next destination.

The data buffer 812 also receives the four clock signals WCK_t/c and outputs them as appropriate strobe signals DQS_t/c[3:0] to support control the four DDR5 x8 chips 820/822/830/832.

The RCD 816 has the same structure and operation as RCD 416 and is not further discussed for purposes of brevity.

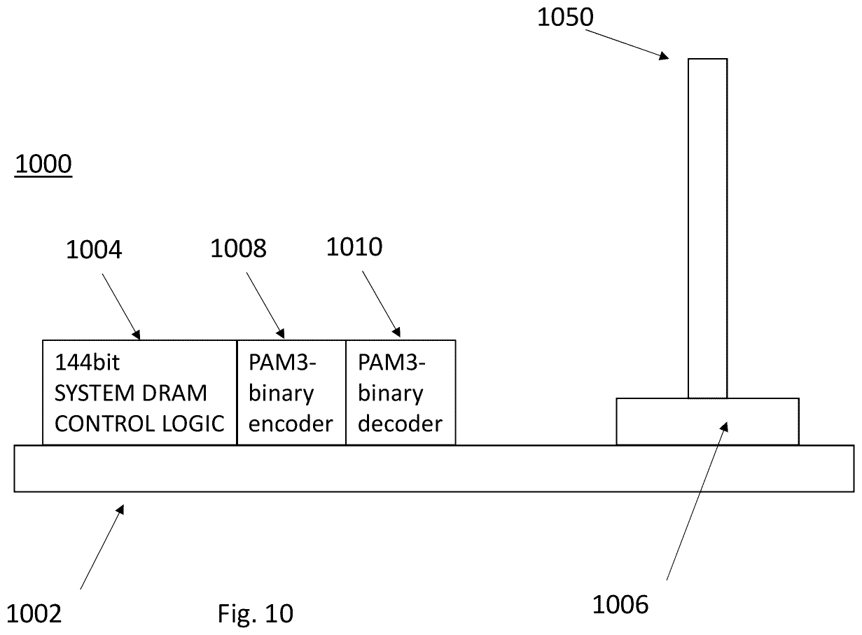

Referring now to FIG. 10, a configuration 1000 for DIMM 1050 is shown. DIMM 1050 may be an in DIMM consistent with disclosed herein, such as DIMM 400 or 700. A printed circuit board 1002 supports a DRAM controller 1004, a socket 1006, and DIMM 400. DRAM controller 1004 includes, or cooperates with, a PAM3-binary encoder 1010 and a PAM3-binary decoder 1012. PAM3-binary decoder 1012 converts binary data and command NRZ signals from DRAM controller 1004 into PAM3 format for dispatch to DIMM 400, and PAM3-binary encoder 1010 converts PAM3 format signals from DIMM 400 into binary NRZ format for DRAM controller 1004.

The specification and drawings are to be regarded in an illustrative rather than a restrictive sense. It will, however, be evident that various modifications and changes may be made thereunto without departing from the broader spirit and scope of the invention as set forth in the claims.

What is claimed is:

1. A Dual In-line Memory Module (DIMM), comprising:
a plurality Double Data Rate (DDR) chips;
a pin array;
a plurality of first data buffers, each of the first data buffers being connected to at least two of the DDRchips, each of the first data buffers comprising:
a Pulse Amplitude Modulation 3-level (PAM3)-binary decoder configured to convert incoming data PAM3 signals from the pin array into one or more incoming 8-bit data signals;
a data demultiplexer configured to forward the one or more incoming 8-bit data signals toward an appropriate one of the connected at least two DDRchips;
a multiplexer configured to receive outgoing 8-bit data signals from the connected at least two DDRchips;
a binary-PAM3 binary encoder configured to convert the outgoing 8-bit data signals from the multiplexer into outgoing PAM3 signals and to forward the outgoing PAM3 signals toward the pin array;
a registered clock driver (RCD), comprising:
a PAM3-binary converter configured to convert incoming driver PAM3 signals into binary driver signals; and
at least one driver demultiplexer and at least one RCD buffer configured to forward at least a portion of the binary driver signals to appropriate ones of the plurality of DDRchips.

2. The DIMM of claim 1, wherein the plurality of DDRchips are DDR5 chips.

3. The DIMM of claim 1, wherein the plurality of DDRchips are grouped into first, second, third and fourth sets of DDRchips.

4. The DIMM of claim 3, wherein each of the sets of DDRchips includes 9 DDR x16 chips.

5. The DIMM of claim 3, wherein:
the at least one driver demultiplexer comprises first and second driver demultiplexers and the and at least one RCD buffer comprises first, second, third and fourth RCD buffers;
the first driver demultiplexer being connected to the first and the second RCD buffers,
the first RCD buffer being connected to the first set of DDRchips by at least one first bus, and the second RCD buffer connected to the second set of DDRchips by at least one second bus;
the second driver demultiplexer being connected to the third and the fourth RCD buffers; and
the third RCD buffer being connected to the third set of DDRchips by at least one third bus, and the fourth RCD buffer connected to the fourth set of DDRchips by at least one fourth bus.

6. The DIMM of claim 1, wherein each of the first data buffers has on a first side thirteen pins for receiving eleven PAM3 signals and two clock signals.

7. The DIMM of claim 6, wherein the two clock signals are Non-Return to Zero (NRZ) signals.

8. The DIMM of claim 1, wherein each of the first data buffers has on a second side four eight-bit data channels and four clock pair channels to communicate with the at least two connected DDRchips.

9. The DIMM of claim 8, wherein each of the DDRchips is connected to one of the first data buffers by two of the four eight-bit data channels and two of the four clock pair channels.

10. The DIMM of claim 8, wherein the data demultiplexer configured to forward the one or more incoming 8-bit data signals toward an appropriate one of the connected two DDRchips comprises the data demultiplexer being configured to select for a particular 8-bit data signal one of the four eight-bit data channels to forward the particular 8-bit data signal to.

11. The DIMM of claim 1, further comprising:
A system controller in communication with the DIMM, the system controller being configured to communicate PAM3 format data and control signals with the DIMM.

12. A Dual In-line Memory Module (DIMM), comprising:
a plurality Double Data Rate (DDR) chips, the DDRchips being DDR5 x16 chips;
a pin array;
a plurality of first data buffers, each of the first data buffers being connected to two of the DDRchips, each of the first data buffers comprising:
a Pulse Amplitude Modulation 3-level (PAM3)-binary decoder configured to convert incoming data PAM3 signals from the pin array into one or more incoming 8-bit data signals;
a data demultiplexer configured to forward the one or more incoming 8-bit data signals toward an appropriate one of the connected two DDRchips;
a multiplexer configured to receive outgoing 8-bit data signals from the connected two DDRchips;
a binary-PAM3 binary encoder configured to convert the outgoing 8-bit data signals from the multiplexer into outgoing PAM3 signals and to forward the outgoing PAM3 signals toward the pin array;
a registered clock driver (RCD), comprising:
a PAM3-binary converter configured to convert incoming driver PAM3 signals into binary driver signals; and
at least one driver demultiplexer and at least one RCD buffer configured to forward at least a portion of the binary driver signals to appropriate ones of the plurality of DDRchips.

13. The DIMM of claim 12, wherein each of the first data buffers has on a first side thirteen pins for receiving eleven PAM3 signals and two clock signals.

14. The DIMM of claim 13, wherein the two clock signals are Non-Return to Zero (NRZ) signals.

15. The DIMM of claim 12, wherein each of the first data buffers has on a second side four eight-bit data channels and four clock pair channels to communicate with the two connected DDRchips.

16. The DIMM of claim 15, wherein the data demultiplexer configured to forward the one or more incoming 8-bit data signals toward an appropriate one of the connected two DDRchips comprises the data demultiplexer being configured to select for a particular 8-bit data signal one of the four eight-bit data channels to forward the particular 8-bit data signal to.

17. A dual in-line memory module (DIMM), comprising:
a plurality Double Data Rate (DDR) chips;
a pin array;
a plurality of first data buffers, each of the first data buffers being connected to four of the DDRchips, each of the first data buffers comprising:
a Pulse Amplitude Modulation 3-level (PAM3)-binary decoder configured to convert incoming data PAM3 signals from the pin array into one or more incoming 8-bit data signals;
a data demultiplexer configured to forward the one or more incoming 8-bit data signals toward an appropriate one of the connected four DDRchips;
a multiplexer configured to receive outgoing 8-bit data signals from the connected four DDRchips;
a binary-PAM3 binary encoder configured to convert the outgoing 8-bit data signals from the multiplexer into outgoing PAM3 signals and to forward the outgoing PAM3 signals toward the pin array;
a registered clock driver (RCD), comprising:
a PAM3-binary converter configured to convert incoming driver PAM3 signals into binary driver signals; and
at least one driver demultiplexer and at least one RCD buffer configured to forward at least a portion of the binary driver signals to appropriate ones of the DDR chips.

18. The DIMM of claim 17, wherein the DDRchips are DDR5 chips.

19. The DIMM of claim 17, wherein the plurality of DDRchips are grouped into first, second, third and fourth sets of DDRchips.

20. The DIMM of claim 19, wherein each set of DDRchips includes 18 DDR x8 chips.
